(19) United States
(12) Patent Application Publication
(10) Pub. No.: US 2025/0151552 A1
(43) Pub. Date: May 8, 2025

(54) DISPLAY APPARATUS

(71) Applicant: Samsung Display Co., Ltd., Yongin-Si (KR)

(72) Inventor: Chulhyun Choi, Yongin-si (KR)

(21) Appl. No.: 18/900,890

(22) Filed: Sep. 30, 2024

(30) Foreign Application Priority Data
Nov. 6, 2023 (KR) 10-2023-0151936

(51) Int. Cl. H10K 59/131; H10K 59/122

(52) U.S. Cl. CPC H10K 59/131; H10K 59/122

(57) ABSTRACT

Provided is a display apparatus including a driving voltage line disposed on an inorganic insulating layer, a first wiring located adjacent to one side of the driving voltage line, a second wiring located adjacent to another side of the driving voltage line, an organic insulating layer disposed on the driving voltage line, the first wiring, and the second wiring, a pixel electrode disposed on the organic insulating layer, and a pixel defining layer including an opening that exposes the pixel electrode. One edge of the pixel defining layer overlaps the first wiring in a plan view.

### CROSS-REFERENCE TO RELATED APPLICATION

This application is based on and claims priority under 35 U.S.C. § 119 to Korean Patent Application No. 10-2023-0151936, filed on Nov. 6, 2023, in the Korean Intellectual Property Office, the disclosure of which is incorporated by reference herein in its entirety.

### BACKGROUND

### 1. Field

One or more embodiments relate to display apparatuses, and more particularly, to a display apparatus enabling a viewer to view high-quality images.

### 2. Description of the Related Art

Organic light-emitting display apparatuses include an organic light-emitting diode as a display device. An organic light-emitting diode includes a pixel electrode, an opposite electrode, and an emission layer interposed between the pixel electrode and the opposite electrode. Organic light-emitting display apparatuses include an electronic device and/or wirings for controlling electrical signals applied to such organic light-emitting diodes.

### SUMMARY

However, such a conventional organic light-emitting display apparatus has a problem in that images with different color coordinates may be recognized depending on a viewing angle from which the display apparatus is viewed.

One or more embodiments include a display apparatus enabling a viewer to watch a high-quality image. However, aspects of embodiments are not limited thereto, and the above characteristics do not limit the scope of embodiments according to the disclosure.

Additional aspects will be set forth in portion in the description which follows and, in part, will be apparent from the description, or may be learned by practice of the presented embodiments of the disclosure.

According to one or more embodiments, a display apparatus includes an inorganic insulating layer disposed over a substrate, a driving voltage line disposed on the inorganic insulating layer, a first wiring disposed on the inorganic insulating layer and located adjacent to one side of the driving voltage line, a second wiring disposed on the inorganic insulating layer and located adjacent to another side of the driving voltage line, an organic insulating layer disposed on the driving voltage line, the first wiring, and the second wiring, a pixel electrode disposed on the organic insulating layer, and a pixel defining layer including an opening that exposes the pixel electrode. One edge of the pixel defining layer overlaps the first wiring in a plan view.

Another edge of the pixel defining layer which opposes the one edge of the pixel defining layer overlaps the second wiring in a plan view.

The first wiring and the second wiring may extend along the second side.

A portion of the first wiring may be disposed within the opening in a plan view. A portion of the second wiring may be disposed within the opening in a plan view.

A distance from an upper surface of a portion of the first electrode portion overlapping the driving voltage line to an upper surface of the substrate may be equal to a distance from an upper surface of another portion of the first electrode portion overlapping the first wiring to the upper surface of the substrate.

The distance from the upper surface of the portion of the first electrode portion overlapping the driving voltage line to the upper surface of the substrate may be different from a distance from an upper surface of another portion of the first electrode portion disposed between the first wiring and the driving voltage line in a plan view to the upper surface of the substrate.

The distance from the upper surface of the portion of the first electrode portion overlapping the driving voltage line to the upper surface of the substrate may be equal to a distance from an upper surface of another portion of the first electrode portion overlapping the second wiring to the upper surface of the substrate.

The distance from the upper surface of the portion of the first electrode portion overlapping the driving voltage line to the upper surface of the substrate may be different from a distance from an upper surface of another portion of the first electrode portion disposed between the second wiring and the driving voltage line in a plan view to the upper surface of the substrate.

The first wiring and the second wiring may include the same material as the driving voltage line.

The display apparatus may further include an emission layer disposed on the pixel electrode, and an opposite electrode disposed on the emission layer.

According to one or more embodiments, a display apparatus includes an inorganic insulating layer disposed over a substrate, a driving voltage line disposed on the inorganic insulating layer, a first wiring disposed on the inorganic insulating layer and located adjacent to one side of the driving voltage line, a second wiring disposed on the inorganic insulating layer and located adjacent to another side of the driving voltage line, an organic insulating layer disposed on the driving voltage line, the first wiring, and the second wiring, a first pixel electrode disposed on the organic insulating layer, a second pixel electrode disposed on the organic insulating layer, and a pixel defining layer including a first opening and a second opening that expose the first pixel electrode and the second pixel electrode, respectively. The driving voltage line is disposed between the first wiring and the second wiring. One edge of the pixel defining layer may overlap the first wiring in a plan view and another edge of the pixel defining layer which opposes the one edge of the pixel defining layer may overlap the second wiring in a plan view.

The first wiring, the driving voltage line, and the second wiring may be arranged to be spaced apart from each other in a first direction, the first pixel electrode and the second pixel electrode may be arranged to be spaced apart from each other in a second direction that interests the first direction, and the driving voltage line may extend in the second direction.

The first wiring may extend in the second direction, and the second wiring may extend in the second direction.

A portion of the first wiring may be disposed within the first opening in a plan view. Another portion of the first wiring may be disposed within the second opening in a plan view. A portion of the second wiring may be disposed within the first opening in a plan view, and another portion of the second wiring may be disposed within the second opening in a plan view.

A distance from an upper surface of the first pixel electrode overlapping the driving voltage line to an upper surface of the substrate may be equal to a distance from an upper surface of the first pixel electrode overlapping the first wiring to the upper surface of the substrate. The distance from the upper surface of the first pixel electrode overlapping the driving voltage line to the upper surface of the substrate may be different from a distance from an upper surface of the first pixel electrode disposed between the first wiring and the driving voltage line in a plan view to the upper surface of the substrate.

A distance from an upper surface of the second pixel electrode overlapping the driving voltage line to the upper surface of the substrate may be equal to a distance from an upper surface of the second pixel electrode overlapping the first wiring to the upper surface of the substrate. The distance from the upper surface of the second pixel electrode overlapping the driving voltage line to the upper surface of the substrate may be different from a distance from an upper surface of the second pixel electrode disposed between the first wiring and the driving voltage line in a plan view to the upper surface of the substrate.

The distance from the upper surface of the first pixel electrode overlapping the driving voltage line to the upper surface of the substrate may be equal to a distance from an upper surface of the first pixel electrode overlapping the second wiring to the upper surface of the substrate. The distance from the upper surface of the portion of the first pixel electrode overlapping the driving voltage line to the upper surface of the substrate may be different from a distance from an upper surface of the first pixel electrode disposed between the second wiring and the driving voltage line in a plan view to the upper surface of the substrate.

A distance from an upper surface of the second pixel electrode overlapping the driving voltage line to the upper surface of the substrate may be equal to a distance from an upper surface of the second pixel electrode overlapping the second wiring to the upper surface of the substrate. The distance from the upper surface of the second pixel electrode overlapping the driving voltage line to the upper surface of the substrate may be different from a distance from an upper surface of the second pixel electrode disposed between the second wiring and the driving voltage line in a plan view to the upper surface of the substrate.

The first wiring and the second wiring may include the same material as the driving voltage line.

The display apparatus may further include a first emission layer disposed on the first pixel electrode, a second emission layer disposed on the second pixel electrode, and an opposite electrode disposed on the first emission layer and the second emission layer.

These and/or other aspects will become apparent and more readily appreciated from the following description of the embodiments, the claims, and the accompanying drawings.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to an embodiment;

FIG. 2 is an equivalent circuit diagram of one pixel circuit included in a display apparatus according to an embodiment;

FIG. 3 is a schematic magnified plan view of a portion A of the display apparatus of FIG. 1;

FIG. 4 is a schematic cross-sectional view taken along line B-B′ of the display apparatus of FIG. 3;

FIG. 5 is a schematic magnified plan view of a portion A of the display apparatus of FIG. 1;

FIG. 6 is a schematic cross-sectional view taken along line C-C′ of the display apparatus of FIG. 5;

FIG. 7 is a schematic cross-sectional view of a display apparatus according to a comparative example;

FIG. 8 is a graph schematically showing a change in luminance according to a change in viewing angle of a display apparatus;

FIG. 9 is a graph schematically showing a change in color coordinates according to a change in viewing angle of a display apparatus according to an embodiment; and

FIG. 10 is a graph schematically showing a change in color coordinates according to a change in viewing angle of a display apparatus according to a comparative example.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, particular embodiments will be illustrated in the drawings and described in detail in the written description. Hereinafter, effects and features of the disclosure and a method for accomplishing them will be described more fully with reference to the accompanying drawings, in which embodiments of the disclosure are shown. The disclosure may, however, be embodied in many different forms and should not be construed as limited to the embodiments set forth herein.

It will be understood that although the terms “first,” “second,” etc. may be used herein to describe various components, these components should not be limited by these terms. These components are only used to distinguish one component from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

In the present specification, “A and/or B” represents A or B, or A and B. The expression “at least one of A and B” indicates only A, only B, both A and B, or variations thereof.

It will be understood that, unless otherwise specified, when an element such as a layer, film, region or substrate is referred to as being “on” another element, it can be “directly” on the other element or intervening elements may also be present.

When a layer, region, or component is referred to as being “connected” or “coupled” to another layer, region, or component, it can be directly connected or coupled to the other layer, region, or/and component or intervening layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

The expression “in a plan view” used herein refers to when an object portion is viewed from the top. In other words, the expression “in a plan view” used herein may refer to “when viewed in a direction perpendicular to a substrate 100”.

An “upper surface” of a component may refer to a surface of the component in a +z direction, and a “lower surface” of a component may refer to a surface of the component in a −z direction.

One or more embodiments of the disclosure will be described below in more detail with reference to the accompanying drawings. Those components that are the same as or are in correspondence with each other are rendered the same reference numeral regardless of the figure number, and redundant explanations are omitted. In the drawings, the thicknesses of layers and regions are exaggerated or reduced for convenience of explanation. For example, since sizes and thicknesses of components in the drawings are arbitrarily illustrated for convenience of explanation, embodiments are not limited thereto.

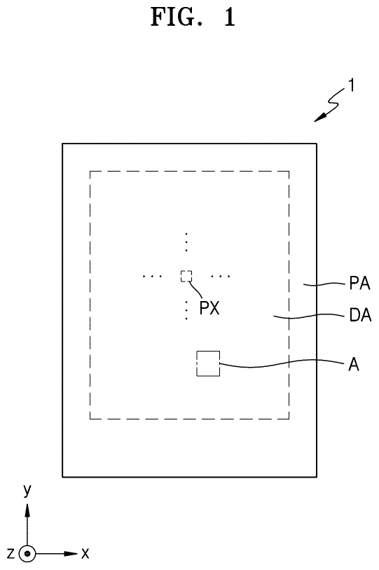

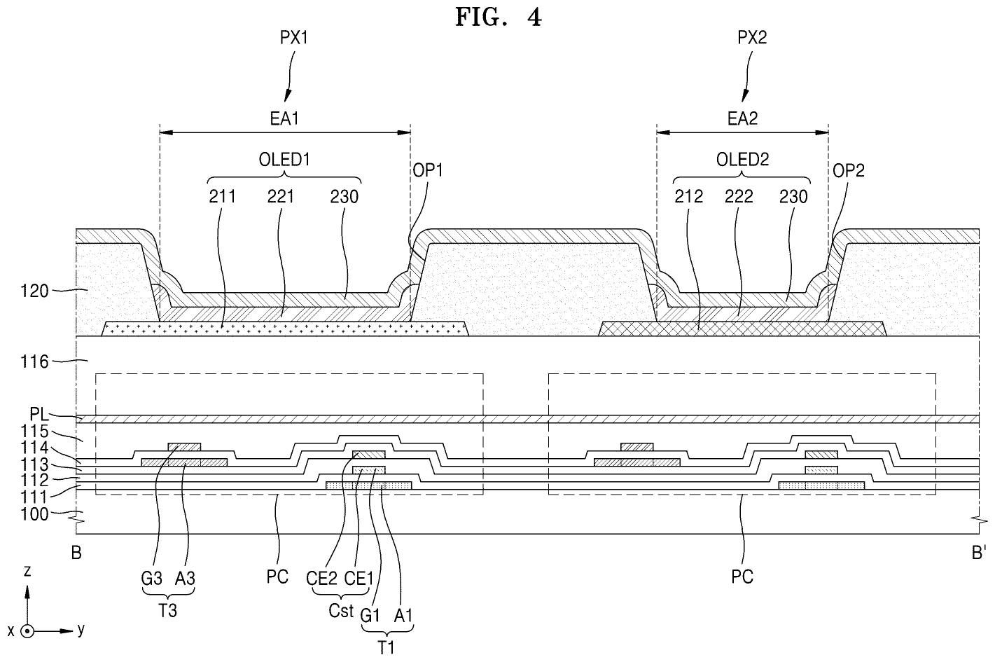

FIG. 1 is a schematic plan view of a display apparatus 1 according to an embodiment. As shown in FIG. 1, the display apparatus 1 may include a display area DA in which a plurality of pixels PX are arranged, and a peripheral area PA located outside the display area DA. In detail, the peripheral area PA may surround the entire display area DA. This may be understood as a substrate 100 of FIG. 4 included in the display apparatus 1 having the display area DA and the peripheral area PA.

Each of the plurality of pixels PX of the display apparatus 1 may emit light of a predetermined color. For example, each of the plurality of pixels PX may emit green light, red light, or blue light. For example, the pixel PX may include a display element, such as an organic light-emitting diode OLED. The display apparatus 1 may provide an image by using light emitted by the pixels PX. Herein, the green light belongs to a wavelength band of 495 nm to 580 nm, the red light belongs to a wavelength band of 580 nm to 780 nm, and the blue light belongs to a wavelength band of 400 nm to 495 nm.

The display area DA may have the shape of a polygon including a quadrangle, as shown in FIG. 1. For example, the display area DA may have a rectangular shape in which a horizontal length is less than a vertical length, a rectangular shape in which a horizontal length is greater than a vertical length, or a square shape. Alternatively, the display area DA may have any of various shapes such as an oval or a circle.

The peripheral area PA may be a non-display area in which no pixels PX are disposed. A driver or the like for providing an electrical signal or power to the pixels PX may be arranged in the peripheral area PA. Pads (not shown) where various electronic devices or printed circuit boards (PCBs) may be electrically connected to the display apparatus 1 may be disposed in the peripheral area PA. The pads are arranged spaced apart from each other in the peripheral area PA, and may be electrically connected to a PCB or an integrated circuit device.

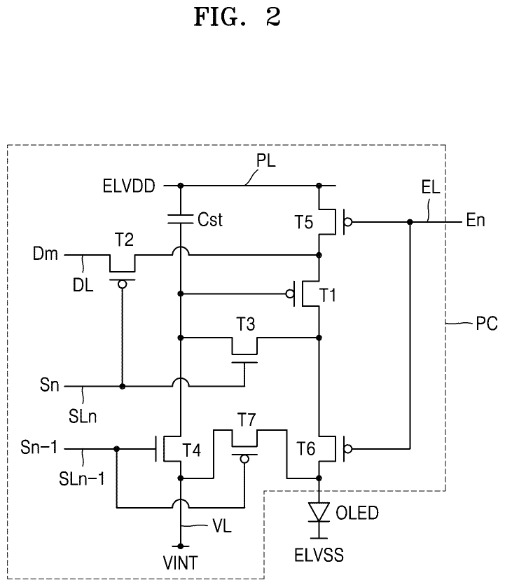

FIG. 2 is an equivalent circuit diagram of one pixel circuit PC included in the display apparatus 1 according to an embodiment. The pixel PX of the display apparatus 1 includes a display element, and the pixel circuit PC may be electrically connected to the display element. In FIG. 2, an organic light-emitting diode OLED is shown as a display element.

As illustrated in FIG. 2, the pixel circuit PC may include a plurality of transistors T1 through T7 and a storage capacitor Cst. The pixel circuit PC may include a plurality of signal lines SLn, SLn-1, EL, and DL, an initializing voltage line VL, and a driving voltage line PL. The plurality of transistors T1 through T7 and the storage capacitor Cst may be connected to the plurality of signal lines SLn, SLn-1, EL, and DL, the initializing voltage line VL, and the driving voltage line PL.

Although each pixel circuit PC includes the plurality of signal lines SLn, SLn-1, EL, and DL, the initializing voltage line VL, and the driving voltage line PL in FIG. 2, embodiments are not limited thereto. According to another embodiment, at least one of the plurality of signal lines SLn, SLn-1, EL, and DL, and/or at least one of the initializing voltage line VL and the driving voltage line PL may be shared by neighboring pixel circuits PC.

The plurality of transistors T1 through T7 may include a driving transistor T1, a switching transistor T2, a compensating transistor T3, a first initializing transistor T4, an operation control transistor T5, a light-emission control transistor T6, and a second initializing transistor T7. Some of the plurality of transistors T1 through T7 may be n-channel MOSFETs (NMOSs), and the others may be p-channel MOSFETs (PMOSs). For example, among the plurality of transistors T1 through T7, the compensating transistor T3 and the first initializing transistor T4 may be n-channel MOSFETs (NMOSs), and the others may be p-channel MOSFETs (PMOSs). Alternatively, among the plurality of transistors T1 through T7, the compensating transistor T3, the first initializing transistor T4, and the second initializing transistor T7 may be NMOS and the others may be PMOS. Alternatively, all of the plurality of transistors T1 through T7 may be NMOS or PMOS. The plurality of transistors T1 through T7 may include amorphous silicon or polysilicon. In some case, transistor that is an NMOS may include an oxide semiconductor. Hereinafter, for convenience of description, a case in which the compensating transistor T3 and the first initializing transistor T4 are NMOS including an oxide semiconductor and the others are PMOS will be described.

The plurality of signal lines SLn, SLn-1, EL, and DL may include a scan line SLn, a previous scan line SLn-1, an emission control line EL, and a data line DL. The scan line SL1 may transmit a scan signal Sn, the previous scan line SLn-1 may transmit a previous scan signal Sn-1, the emission control line EL may transmit an emission control signal En, and the data line DL may transmit a data signal Dm. The initializing voltage line VL may transmit a initializing voltage VINT, and the driving voltage line PL may transmit a first power supply voltage ELVDD (or a driving voltage).

A drain region of the driving transistor T1 may be electrically connected to the organic light-emitting diode OLED via the light-emission control transistor T6. The driving transistor T1 may receive the data signal Dm according to a switching operation of the switching transistor T2 and may supply a driving current to the organic light-emitting diode OLED.

A gate electrode of the switching transistor T2 may be connected to the scan line SL, and a source electrode thereof may be connected to the data line DL. A drain region of the switching transistor T2 may be connected to a source region of the driving transistor T1 and at the same time may be connected to the driving voltage line PL via the operation control transistor T5.

The switching transistor T2 may be turned on in response to the scan signal Sn received via the scan line SL and may perform a switching operation of transmitting the data signal Dm received from the data line DL to the source electrode of the driving transistor T1.

A gate electrode of the compensating transistor T3 may be connected to the scan line SLn. A source region of the compensating transistor T3 may be connected to the drain region of the driving transistor T1 and at the same time may be connected to a pixel electrode of the organic light-emitting diode OLED via the light-emission control transistor T6. A drain region of the compensating transistor T3 may be connected to one electrode of the storage capacitor Cst, a source region of the first initializing transistor T4, and a gate electrode of the driving transistor T1. The compensating transistor T3 is turned on according to the scan signal Sn received via the scan line SL and connects the gate electrode and the drain region of the driving transistor T1 to each other, thus achieving diode-connection of the driving transistor T1.

A gate electrode of the first initializing transistor T4 may be connected to the previous scan line SLn-1. A drain region of the first initializing transistor T4 may be connected to the initializing voltage line VL. A source region of the first initializing transistor T4 may be connected to the one electrode of the storage capacitor Cst, the drain region of the compensating transistor T3, and the gate electrode of the driving transistor T1. The first initializing transistor T4 may be turned on in response to the previous scan signal Sn-1 received via the previous scan line SLn-1 and may transmit the initializing voltage Vint to the gate electrode of the driving transistor T1 to thereby initialize a voltage of the gate electrode of the driving transistor T1.

A gate electrode of the operation control transistor T5 may be connected to the light-emission control line EL. A source region of the operation control transistor T5 may be connected to the driving voltage line PL. A drain region of the operation control transistor T5 is connected to the source region of the driving transistor T1 and the drain region of the switching transistor T2.

A gate electrode of the light-emission control transistor T6 may be connected to the light-emission control line EL. A source region of the light-emission control transistor T6 may be connected to the drain region of the driving transistor T1 and the source region of the compensating transistor T3. A drain region of the light-emission control transistor T6 may be electrically connected to the pixel electrode of the organic light-emitting diode OLED. The operation control transistor T5 and the light-emission control transistor T6 are simultaneously turned on in response to a light-emission control signal En received via the emission control line EL and thus the first power supply voltage ELVDD is transmitted to the organic light-emitting diode OLED, and the driving current flows through the organic light-emitting diode OLED.

A gate electrode of the second initializing transistor T7 may be connected to the previous scan line SLn-1. A source region of the second initializing transistor T7 may be connected to the pixel electrode of the organic light-emitting diode OLED. A drain region of the second initializing transistor T7 may be connected to the initializing voltage line VL. The second initializing transistor T7 may be turned on in response to the previous scan signal Sn-1 received via the previous scan line SLn-1 and may initialize the pixel electrode of the organic light-emitting diode OLED.

Although the first initializing transistor T4 and the second initializing transistor T7 are connected to the previous scan line SLn-1 in FIG. 2, the disclosure is not limited thereto. According to another embodiment, the first initializing transistor T4 may be connected to the previous scan line SLn-1 and operate in response to the previous scan signal Sn-1, and the second initializing transistor T7 may be connected to a separate signal line (for example, a subsequent scan line) and operate in response to a signal transmitted to the separate signal line.

The one electrode of the storage capacitor Cst may be connected to the gate electrode of the driving transistor T1, the drain region of the compensating transistor T3, and the source region of the first initializing transistor T4. Another electrode of the storage capacitor Cst may be connected to the driving voltage line PL.

An opposite electrode (for example, a cathode) of the organic light-emitting diode OLED receives a second power supply voltage ELVSS (or a common voltage). The organic light-emitting diode OLED may receive the driving current from the driving transistor T1 and emit light.

Although a case where the pixel circuit PC includes seven transistors and one storage capacitor is illustrated in FIG. 2, the disclosure is not limited thereto. The number of transistors included in the pixel circuit PC and the number of storage capacitors included in the pixel circuit PC may vary according to a design of the pixel circuit PC.

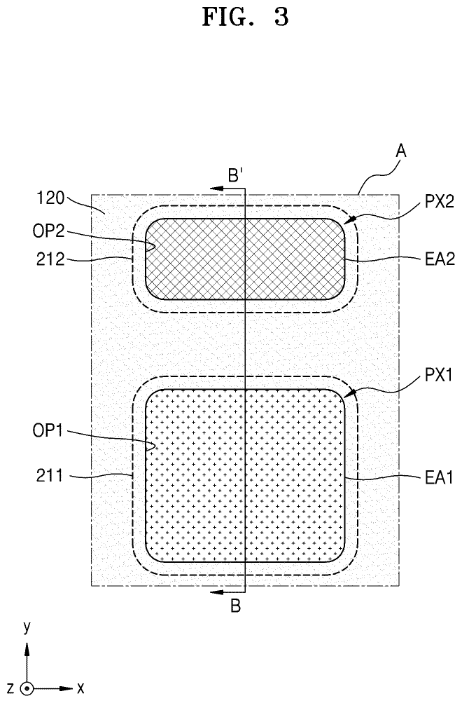

FIG. 3 is a schematic magnified plan view of a portion A of the display apparatus 1 of FIG. 1. FIG. 3 illustrates a plan view on a pixel definition layer 120 for convenience.

As shown in FIG. 3, a plurality of pixels PX may be arranged in the display area DA of the substrate 100. Each of the plurality of pixels PX may refer to a subpixel and may include a display element such as an organic light-emitting diode OLED. Each of the plurality of pixels PX may emit, for example, green light, red light, or blue light. For example, the pixel PX may be a first pixel PX1 that emits light of a first color or a second pixel PX2 that emits light of a second color different from the first color. For example, the light of the first color may be green light, and the light of the second color may be red light. However, the disclosure is not limited thereto.

Although not shown in FIG. 3, a third pixel that emits light of a third color different from the light of the first color and the light of the second color may be further disposed in the display area DA of the substrate 100. In this case, the light of the first color may be green light, the light of the second color may be red light, and the light of the third color may be blue light. However, the disclosure is not limited thereto.

A first pixel electrode 211 included in the first pixel PX1 and a second pixel electrode 212 included in the second pixel PX2 may be disposed in the display area DA. For example, the first pixel electrode 211 and the second pixel electrode 212 may be spaced apart from each other in a plan view. In detail, in a plan view, the first pixel electrode 211 and the second pixel electrode 212 may be arranged spaced apart from each other in a second direction (e.g., a y-axis direction) that intersects a first direction (e.g., an x-axis direction). The first pixel electrode 211 and the second pixel electrode 212 may have different sizes as shown in FIG. 3. According to another embodiment, the first pixel electrode 211 and the second pixel electrode 212 may have the same sizes.

The pixel defining layer 120 may be disposed over the first pixel electrode 211 and the second pixel electrode 212, and may define a first opening OP1 and a second opening OP2. In a plan view, the first opening OP1 and the second opening OP2 may be spaced apart from each other in the second direction (for example, the y-axis direction) intersecting the first direction (for example, the x-axis direction). The first opening OP1 may expose a center portion of the first pixel electrode 211, and the second opening OP2 may expose a center portion of the second pixel electrode 212. The first opening OP1 and the second opening OP2 may have different sizes as shown in FIG. 3. According to another embodiment, the first opening OP1 and the second opening OP2 may have the same sizes.

Although not shown in FIG. 3, emission layers that emit light may be located within the first opening OP1 and the second opening OP2 of the pixel defining layer 120, respectively. Opposite electrodes may be disposed on these emission layers. A stacked structure of a pixel electrode, an emission layer, and an opposite electrode may form one organic light-emitting diode OLED. One opening of the pixel defining layer 120 may correspond to one organic light-emitting diode OLED and may define one emission area. For example, an emission layer that emits the light of the first color may be disposed in the first opening OP1, and the first opening OP1 may define a first emission area EA1 of the first pixel PX1. Similarly, an emission layer that emits the light of the second color may be disposed in the second opening OP2, and the second opening OP2 may define a second emission area EA2 of the second pixel PX2.

FIG. 4 is a schematic cross-sectional view taken along line B-B′ of the display apparatus 1 of FIG. 3.

Referring to FIG. 4, the display apparatus 1 includes the substrate 100. The substrate 100 may include glass, a metal, or a polymer resin. The substrate 100 may have flexible or bendable characteristics. In this case, the first substrate 100 may include polymer resin such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layered structure including two layers each including a polymer resin and a barrier layer including an inorganic material (silicon oxide (SiO_{X}), silicon nitride (SiN_{X}), silicon oxynitride (SiO_{X}N_{Y}), or the like) and located between the two layers. In this way, various modifications may be made.

A display element included in each pixel PX, and a pixel circuit PC electrically connected to the display element may be disposed on the substrate 100. In FIG. 4, each pixel PX includes an organic light-emitting diode OLED as the display element. For example, the organic light-emitting diode OLED may be a first organic light-emitting diode OLED1 or a second organic light-emitting diode OLED2. In other words, the first organic light-emitting diode OLED1 may be included in the first pixel PX1, and the second organic light-emitting diode OLED2 may be included in the second pixel PX2. In detail, the first organic light-emitting diode OLED1 included in the first pixel PX1 and a pixel circuit PC electrically connected to the first organic light-emitting diode OLED1 may be disposed on the substrate 100. The second organic light-emitting diode OLED2 included in the second pixel PX2 and a pixel circuit PC electrically connected to the second organic light-emitting diode OLED2 may be disposed on the substrate 100.

A display element electrically connected to the pixel circuit PC may be a pixel electrode of the display element. Although electrical connection between the pixel electrode of the display element and the pixel circuit PC is not shown in detail in FIG. 4, the pixel electrode of the display element may be electrically connected to the pixel circuit PC disposed below the display element. For example, the first pixel electrode 211 of the first organic light-emitting diode OLED1 may be electrically connected to a pixel circuit PC located in a lower left portion of FIG. 4, and the second pixel electrode 212 of the second organic light-emitting diode OLED2 may be electrically connected to a pixel circuit PC located in a lower right portion of FIG. 4. Because respective pixel circuits PC of the plurality of pixels PX have the same structures, a description will focus on one pixel circuit PC.

As described above, the pixel circuit PC may include the driving transistor T1, the switching transistor T2, the compensating transistor T3, the first initializing transistor T4, the operation control transistor T5, the light-emission control transistor T6, and the second initializing transistor T7. However, in FIG. 4, only the driving transistor T1 and the compensating transistor T3 are shown for convenience of illustration. The driving transistor T1 may include a first semiconductor layer A1 and a first gate electrode G1, and the compensating transistor T3 may include a third semiconductor layer A3 and a third gate electrode G3. The pixel circuit PC may include the scan line SLn, the previous scan line SLn-1, the emission control line EL, the data line DL, the initializing voltage line VL, and the driving voltage line PL. For convenience of illustration, FIG. 4 does not illustrate the scan line SLn, the previous scan line SLn-1, the emission control line EL, the data line DL, and the initializing voltage line VL.

A silicon semiconductor layer including a silicon semiconductor material may be disposed on the substrate 100. FIG. 4 shows the first semiconductor layer A1 of the driving transistor T1 as a silicon semiconductor layer. The first semiconductor layer A1 may include a first channel region, and a first source region and a second drain region respectively arranged on both sides of the first channel region. The first source region and the first drain region may be doped with impurities that may include N-type impurities or P-type impurities. The first channel region is a region that overlaps with the first gate electrode G1 in a plan view, which will be described later, and may be undoped with impurities or may include a very small amount of impurities.

A first inorganic insulating layer 111 may be disposed on the first semiconductor layer A1. The first inorganic insulating layer 111 may include an inorganic material. For example, the first inorganic insulating layer 111 may include an inorganic insulating material such as silicon oxide (SiO_{X}), silicon nitride (SiN_{X}), or silicon oxynitride (SiO_{X}N_{Y}), and may have a single-layer or multi-layer structure including the above-mentioned material.

The first gate electrode G1 may be disposed on the first inorganic insulating layer 111. In other words, the first gate electrode G1 may be disposed over the first semiconductor layer A1, and the first inorganic insulating layer 111 may be interposed between the first semiconductor layer A1 and the first gate electrode G1. The first gate electrode G1 may overlap at least a portion of the first semiconductor layer A1. For example, the first gate electrode G1 may overlap the first channel region of the first semiconductor layer A1. The first gate electrode G1 may include a low-resistance conductive material such as molybdenum (Mo), aluminum (Al), copper (Cu), and/or titanium (Ti), and may have a single-layer or multi-layer structure including the aforementioned materials. For example, the first gate electrode G1 may have a single-layer structure of Mo or a multi-layer structure of Mo/Al/Mo.

The storage capacitor Cst may include a first capacitor electrode CE1 and a second capacitor electrode CE2. According to an embodiment, the storage capacitor Cst may be formed to overlap the driving transistor T1. In this case, the first gate electrode G1 may function not only as a gate electrode of the driving transistor T1 but also as the first capacitor electrode CE1. In other words, the first gate electrode G1 and the first capacitor electrode CE1 may be integrally formed with each other. The first capacitor electrode CE1 may be formed as an island-shaped electrode. According to another embodiment, the storage capacitor Cst and the driving transistor T1 may not overlap each other and may exist at a separate location.

A second inorganic insulating layer 112 may be disposed on the first gate electrode G1. The second inorganic insulating layer 112 may include an inorganic material. For example, the second inorganic insulating layer 112 may include an inorganic insulating material such as silicon oxide (SiO_{X}), silicon nitride (SiN_{X}), or silicon oxynitride (SiO_{X}N_{Y}), and may have a single-layer or multi-layer structure including the above-mentioned material.

The second capacitor electrode CE2 may be disposed on the second inorganic insulating layer 112. In detail, the second capacitor electrode CE2 may be disposed on the second inorganic insulating layer 112 to overlap the first capacitor electrode CE1. In other words, the second capacitor electrode CE2 may be disposed over the first capacitor electrode CE1 to overlap the first capacitor electrode CE1, and the second inorganic insulating layer 112 may be interposed between the first capacitor electrode CE1 and the second capacitor electrode CE2. The second inorganic insulating layer 112 may serve as a dielectric layer of the storage capacitor Cst.

The second capacitor electrode CE2 may include a metal, an alloy, a conductive metal oxide, a transparent conductive material, etc. The second capacitor electrode CE2 may include at least one of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may have a single-layered or multi-layered structure including the aforementioned material.

A third inorganic insulating layer 113 may be disposed on the second capacitor electrode CE2. The third inorganic insulating layer 113 may include an inorganic material. For example, the third inorganic insulating layer 113 may include an inorganic insulating material such as silicon oxide (SiO_{X}), silicon nitride (SiN_{X}), or silicon oxynitride (SiO_{X}N_{Y}), and may have a single-layer or multi-layer structure including the above-mentioned material.

A semiconductor layer including a different material from the first semiconductor layer A1 may be disposed on the third inorganic insulating layer 113. For example, an oxide-based semiconductor layer including an oxide semiconductor may be disposed on the third inorganic insulating layer 113. The oxide-based semiconductor layer may include Zn oxide, In—Zn oxide, Ga—In—Zn oxide, or the like as a Zn oxide-based material. According to some embodiments, the oxide-based semiconductor layer may include an In—Ga—Zn—O (IGZO), In—Sn—Zn—O (ITZO), or In—Ga—Sn—Zn—O (IGTZO) semiconductor containing a metal, such as indium (In), gallium (Ga), or tin (Sn), in ZnO. FIG. 4 shows the third semiconductor layer A3 of the driving transistor T3, as an oxide semiconductor layer. The third semiconductor layer A3 may include a third channel region, and a third source region and a third drain region respectively arranged on both sides of the third channel region.

A fourth inorganic insulating layer 114 may be disposed on the third semiconductor layer A3. The fourth inorganic insulating layer 114 may include an inorganic material. For example, the fourth inorganic insulating layer 114 may include an inorganic insulating material such as silicon oxide (SiO_{X}), silicon nitride (SiN_{X}), or silicon oxynitride (SiO_{X}N_{Y}), and may have a single-layer or multi-layer structure including the above-mentioned material.

The third gate electrode G3 may be disposed on the fourth inorganic insulating layer 114. In other words, the third gate electrode G3 may be disposed over the third semiconductor layer A3, and the fourth inorganic insulating layer 114 may be interposed between the third semiconductor layer A3 and the third gate electrode G3. The third gate electrode G3 may at least partially overlap the third semiconductor layer A3. For example, the third gate electrode G3 may overlap the third semiconductor layer A3. The third gate electrode G3 may include a low-resistance conductive material such as molybdenum (Mo), aluminum (Al), copper (Cu), and/or titanium (Ti), and may have a single-layer or multi-layer structure including the aforementioned materials. For example, the third gate electrode G3 may have a single-layer structure of Mo or a multi-layer structure of Mo/Al/Mo.

A fifth inorganic insulating layer 115 may be disposed on the third gate electrode G3. The fifth inorganic insulating layer 115 may cover the third gate electrode G3. The fifth inorganic insulating layer 115 may include an inorganic material. For example, the fifth inorganic insulating layer 115 may include an inorganic insulating material such as silicon oxide (SiO_{X}), silicon nitride (SiN_{X}), or silicon oxynitride (SiO_{X}N_{Y}), and may have a single-layer or multi-layer structure including the above-mentioned material.

The driving voltage line PL may be disposed on the fifth inorganic insulating layer 115. In other words, the fifth inorganic insulating layer 115 may be disposed over the substrate 100, and the driving voltage line PL may be disposed on the fifth inorganic insulating layer 115. The driving voltage line PL may extend in the second direction (e.g., the y-axis direction) intersecting the first direction (e.g., the x-axis direction). Accordingly, a portion of the driving voltage line PL may be disposed under the first organic light-emitting diode OLED1, and another portion of the driving voltage line PL may be disposed under the second organic light-emitting diode OLED2. In other words, the driving voltage line PL may be shared by neighboring pixel circuits PC. The driving voltage line PL may include a conductive material. For example, the driving voltage line PL may include a metal material such as molybdenum (Mo), aluminum (Al), copper (Cu), or titanium (Ti), and may have a single-layer or multi-layer structure including the aforementioned materials. For example, the driving voltage line PL may have a multi-layer structure of Ti/Al/Ti. A detailed description of the driving voltage line PL will be provided later.

Although not shown in FIG. 4, a first source electrode, a first drain electrode, a third source electrode, and a third drain electrode may be arranged on the fifth inorganic insulating layer 115. These source electrodes and drain electrodes may be electrically connected to semiconductor layers through contact holes formed in inorganic insulating layers. In detail, the first source electrode and the first drain electrode may each be electrically connected to the first semiconductor layer A1 via contact holes formed through the first inorganic insulating layer 111, the second inorganic insulating layer 112, the third inorganic insulating layer 113, the fourth inorganic insulating layer 114, and the fifth inorganic insulating layer 115. In other words, the first source electrode may be connected to the first source region of the first semiconductor layer A1, and the first drain electrode may be connected to the first drain region of the first semiconductor layer AL. The third source electrode and the third drain electrode may each be electrically connected to the third semiconductor layer A3 via contact holes formed through the fourth inorganic insulating layer 114 and the fifth inorganic insulating layer 115. In other words, the third source electrode may be connected to the source region of the third semiconductor layer A3, and the third drain electrode may be connected to the drain region of the third semiconductor layer A3.

The first source electrode, the first drain electrode, the third source electrode, and the third drain electrode may be formed simultaneously with the driving voltage line PL and may be formed of the same material as the driving voltage line PL. Accordingly, the first source electrode, the first drain electrode, the third source electrode, and the third drain electrode may be formed of the same material as the driving voltage line PL. In other words, each of the first source electrode, the first drain electrode, the third source electrode, and the third drain electrode may include a conductive material. For example, each of the first source electrode, the first drain electrode, the third source electrode, and the third drain electrode may include a metal material such as molybdenum (Mo), aluminum (Al), copper (Cu), or titanium (Ti), and may have a single-layer or multi-layer structure including the aforementioned materials. For example, each of the first source electrode, the first drain electrode, the third source electrode, and the third drain electrode may have a multi-layer structure of Ti/Al/Ti.

As shown in FIG. 4, an organic insulating layer 116 may be disposed on the driving voltage line PL. Accordingly, the driving voltage line PL may be covered with the organic insulating layer 116. In other words, the organic insulating layer 116 may be disposed on the fifth inorganic insulating layer 115 to cover pixel circuits PC.

The organic insulating layer 116 is a planarization insulating layer, and an upper surface thereof may include an approximately flat surface. The organic insulating layer 116 may include an organic insulating material. For example, the organic insulating layer 116 may include a commercial polymer such as benzocyclobutene (BCB), polyimide, hexamethyldisiloxane (HMDSO), polymethyl methacrylate (PMMA) or polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, or the like. The organic insulating layer 116 may have a single-layer or multi-layer structure including the aforementioned materials.

The first organic light-emitting diode OLED1 and the second organic light-emitting diode OLED2 may be arranged to be spaced apart from each other on the organic insulating layer 116. In detail, the first organic light-emitting diode OLED1 and the second organic light-emitting diode OLED2 disposed adjacent to each other in the second direction (e.g., the y-axis direction) intersecting the first direction (e.g., the x-axis direction) may be arranged on the organic insulating layer 116. The first organic light-emitting diode OLED1 may emit light of a first color, and the second organic light-emitting diode OLED2 may emit light of a second color different from the first color. For example, the light of the first color may be green light, and the light of the second color may be red light. However, the disclosure is not limited thereto.

The first organic light-emitting diode OLED1 may include the first pixel electrode 211, a first emission layer 221, and an opposite electrode 230. The second organic light-emitting diode OLED2 may include the second pixel electrode 212, a second emission layer 222, and the opposite electrode 230. The opposite electrode 230 may be provided integrally over an entire surface of the display apparatus 1, and thus may be provided commonly in a plurality of organic light-emitting diodes.

The first pixel electrode 211 and the second pixel electrode 212 may be spaced apart from each other and disposed on the organic insulating layer 116. In detail, the second pixel electrode 212 may be disposed on the organic insulating layer 116 to be adjacent to the first pixel electrode 211 in the second direction (e.g., the y-axis direction). Each of the first pixel electrode 211 and the second pixel electrode 212 may include a light-transmissive conductive layer formed of a light-transmissive conductive oxide such as ITO, In₂O₃, or IZO, and a reflective layer formed of a metal such as Al or Ag. For example, each of the first pixel electrode 211 and the second pixel electrode 212 may have a three-layered structure of ITO/Ag/ITO. Although not shown in FIG. 4, each of the first pixel electrode 211 and the second pixel electrode 212 may be electrically connected to the pixel circuit PC to a source electrode or a drain electrode. In detail, each of the first pixel electrode 211 and the second pixel electrode 212 may be electrically connected to the driving transistor T1 to the first source electrode or the first drain electrode through a contact hole formed in the organic insulating layer 116 and the inorganic insulating layers 111, 112, 113, 114 and 115.

The pixel defining layer 120 may be disposed over the organic insulating layer 116. The pixel defining layer 120 may include an opening which exposes at least a center portion of a pixel electrode. The opening in the pixel defining layer 120 may correspond to an emission area of a pixel PX. In detail, the pixel defining layer 120 may define the first opening OP1 and the second opening OP2. The first opening OP1 may expose the center portion of the first pixel electrode 211, and the second opening OP2 may expose the center portion of the second pixel electrode 212.

In such a case as illustrated in FIG. 4, the pixel defining layer 120 may increase a distance between an edge of the first pixel electrode 211 and the opposite electrode 230 over the first pixel electrode 211. Similarly, the pixel defining layer 120 may increase a distance between an edge of the second pixel electrode 212 and the opposite electrode 230 over the second pixel electrode 212. Accordingly, an arc or the like may be prevented from occurring between the edge of the first pixel electrode 211 and the edge of the second pixel electrode 212. The pixel defining layer 120 may include an organic material, for example, polyimide or hexamethyldisiloxane HMDSO.

The first emission layer 221 capable of emitting the light of the first color may be disposed on the first pixel electrode 211. In other words, the first emission layer 221 may be interposed between the first pixel electrode 211 and the opposite electrode 230. The second emission layer 222 capable of emitting the light of the second color different from the first color may be disposed on the second pixel electrode 212. In other words, the second emission layer 222 may be interposed between the second pixel electrode 212 and the opposite electrode 230. The light of the first color may be green light, and the light of the second color may be red light.

The first emission layer 221 and the second emission layer 222 may include, for example, an organic material. In detail, the first emission layer 221 and the second emission layer 222 may include a low-molecular or high-molecular weight organic material capable of emitting light of a certain color. For example, the first emission layer 221 may include a high-molecular or low-molecular weight organic material capable of emitting green light, and the second emission layer 222 may include a high-molecular or low-molecular weight organic material capable of emitting red light. For example, the first emission layer 221 and the second emission layer 222 may include a high-molecular weight material such as a polyphenylene vinylene (PPV)-based material or a polyfluorene-based material. The first emission layer 221 and the second emission layer 222 may be formed via screen printing, inkjet printing, laser induced thermal imaging (LITI), or the like. However, the disclosure is not limited thereto.

According to an embodiment, a function layer (not shown) may be disposed below and over the first emission layer 221 and the second emission layer 222. The functional layer may include an hole injection layer (HIL), a hole transport layer (HTL), an electron transport layer (ETL), and/or an electron injection layer (EIL). The functional layer may be integrated to cover the first pixel electrode 211 and the second pixel electrode 212, or may be patterned in correspondence with each of the first pixel electrode 211 and the second pixel electrode 212.

The opposite electrode 230 may be disposed on the first emission layer 221 and the second emission layer 222. The opposite electrode 230 may be integrally formed to cover the first organic light-emitting diode OLED1 and the second organic light-emitting diode OLED2. For example, the opposite electrode 230 may be disposed to overlap both the first pixel electrode 211 and the second pixel electrode 212. The opposite electrode 230 may include a light-transmissive conductive layer formed of ITO, In₂O₃, or IZO, and also include a semi-transmissive layer including a metal such as Al or Ag. For example, the opposite electrode 230 may be a semi-transmissive layer including Mg or Ag.

Because the organic light-emitting diodes OLED may be easily damaged by external moisture, oxygen, or the like, an encapsulation layer (not shown) may cover and protect the organic light-emitting diodes OLED. The encapsulation layer may include a first inorganic encapsulation layer, an organic encapsulation layer, and a second inorganic encapsulation layer, and may cover the display area DA and extend to the outside of the display area DA.

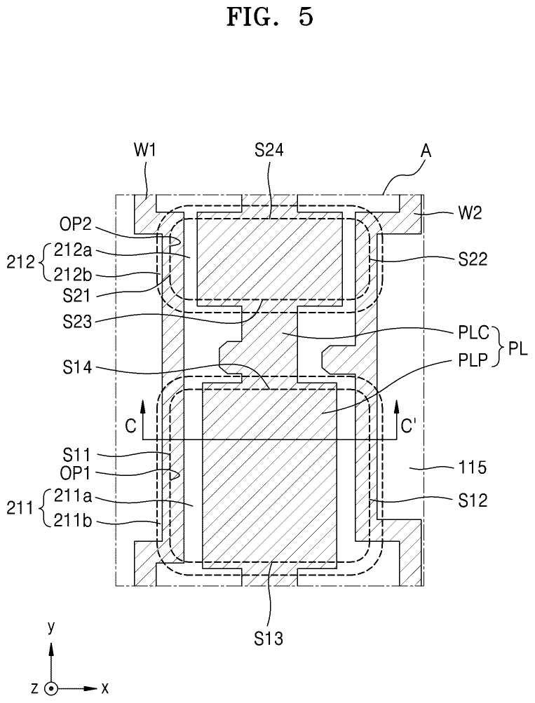

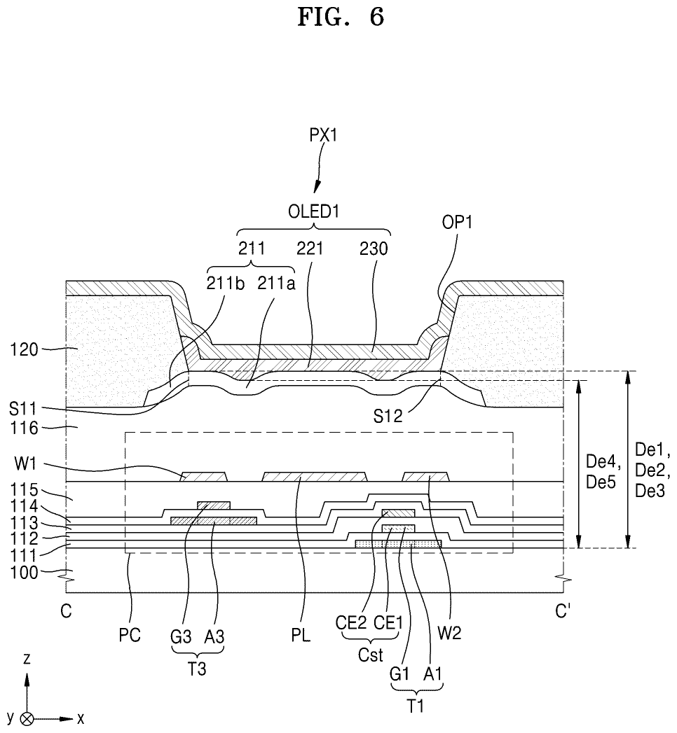

FIG. 5 is a schematic magnified plan view of the portion A of the display apparatus 1 of FIG. 1. FIG. 5 illustrates a plan view of elements disposed on the fifth inorganic insulating layer 115 for convenience. However, for convenience of explanation, the first pixel electrode 211, the second pixel electrode 212, the first opening OP1, and the second opening OP2 are shown together in FIG. 5. FIG. 6 is a schematic cross-sectional view taken along line C-C′ of the display apparatus 1 of FIG. 5.

As described above, the driving voltage line PL may be disposed on the fifth inorganic insulating layer 115. The driving voltage line PL may extend in the second direction (e.g., the y-axis direction) intersecting the first direction (e.g., the x-axis direction). In detail, the driving voltage line PL may include a pattern PLP having an island shape and a connection line PLC connecting patterns PLP disposed adjacent to each other in the second direction (e.g., the y-axis direction). In other words, patterns PLP may be arranged under pixel electrodes, respectively, and may be connected to each other by the connection line PLC. The patterns PLP and the connection line PLC may be integrally formed with each other, and the patterns PLP included in pixel circuits PC may be connected to each other by the connection line PLC, so that the driving voltage line PL located in the same column may be formed as a single body. In other words, the driving voltage line PL may be shared by neighboring pixel circuits PC in the second direction.

In other words, the driving voltage line PL may be disposed under pixel electrodes. In detail, a portion of the driving voltage line PL may be disposed under the pixel electrodes in areas corresponding to openings. In other words, a portion of the driving voltage line PL may be disposed under the first pixel electrode 211 in an area corresponding to the first opening OP1, and another portion of the driving voltage line PL may be disposed under the second pixel electrode 212 in an area corresponding to the second opening OP2.

The first pixel electrode 211 may include a 1-1 electrode portion 211a and a 1-2 electrode portion 211b. The 1-1 electrode portion 211a may be the portion of the first pixel electrode 211 exposed by the first opening OP1, and the 1-2 electrode portion 211b may be a portion of the first pixel electrode 211 that is covered by the pixel definition layer. In other words, the first opening OP1 may expose the 1-1 electrode portion 211a. The 1-1 electrode portion 211a may include a center portion of the first pixel electrode 211, and the 1-2 electrode portion 211b may be located outside the 1-1 electrode portion 211a. In detail, the 1-2 electrode portion 211b may surround the entire 1-1 electrode portion 211a. In other words, the pixel defining layer 120 may not be disposed on the 1-1 electrode portion 211a, but the pixel defining layer 120 may be disposed on the 1-2 electrode portion 211b to cover the 1-2 electrode portion 211b.

Similarly, the second pixel electrode 212 may include a 2-1 electrode portion 212a and a 2-2 electrode portion 212b. The 2-1 electrode portion 212a may be the portion of the second pixel electrode 212 exposed by the second opening OP2, and the 2-2 electrode portion 212b may be a portion of the second pixel electrode 212 that is covered by the pixel definition layer. In other words, the second opening OP2 may expose the 2-1 electrode portion 212a. The 2-1 electrode portion 212a may include a center portion of the second pixel electrode 212, and the 2-2 electrode portion 212b may be located outside the 2-1 electrode portion 212a. In detail, the 2-2 electrode portion 212b may surround the entire 2-1 electrode portion 212a. In other words, the pixel defining layer 120 may not be disposed on the 2-1 electrode portion 212a, but the pixel defining layer 120 may be disposed on the 2-2 electrode portion 212b to cover the 2-2 electrode portion 212b. A portion of the driving voltage line PL may be disposed under the 1-1 electrode portion 211a in an area corresponding to the first opening OP1, and another portion of the driving voltage line PL may be disposed under the 2-1 electrode portion 212a in an area corresponding to the second opening OP2.

An edge of the 1-1 electrode portion 211a may entirely have a shape that is similar to a rectangle or a square. However, as shown in FIG. 5, the 1-1 electrode portion 211a may not have a sharp edge. In detail, the 1-1 electrode portion 211a may include a 1-1 side S11 and a 1-2 side S12 facing each other, and a 1-3 side S13 and a 1-4 side S14 connecting the 1-1 side S11 and the 1-2 side S12. In a plan view, the 2-1 electrode portion 212a is disposed adjacent to the 1-3 side S13 and/or the 1-4 side S14 among the 1-1 through 1-4 sides S11 through S14. The 1-1 side S11 may form a corner by contacting the 1-3 side S13, and the 1-1 side S11 may form a corner by contacting the 1-4 side S14. The 1-2 side S12 may form a corner by contacting the 1-3 side S13, and the 1-2 side S12 may form a corner by contacting the 1-4 side S14. These corners may each have a round shape.

Similarly, an edge of the 2-1 electrode portion 212a may entirely have a shape that is similar to a rectangle or a square. However, as shown in FIG. 5, the 2-1 electrode portion 212a may not have a sharp edge. In detail, the 2-1 electrode portion 212a may include a 1-1 side S11 and a 1-2 side S12 facing each other, and a 1-3 side S13 and a 1-4 side S14 connecting the 1-1 side S11 and the 1-2 side S12. In a plan view, the 1-1 electrode portion 211a is disposed adjacent to the 2-3 side S23 and/or the 2-4 side S24 among the 2-1 through 2-4 sides S21 through S24. The 2-1 side S21 may form a corner by contacting the 2-3 side S23, and the 2-1 side S21 may form a corner by contacting the 2-4 side S24. The 2-2 side S22 may form a corner by contacting the 2-3 side S23, and the 2-2 side S22 may form a corner by contacting the 2-4 side S24. These corners may each have a round shape.

In a plan view, the driving voltage line PL may be disposed between the 1-1 side S11 and the 1-2 side S12 and between the 2-1 side S21 and the 2-2 side S22. In detail, a portion of the driving voltage line PL may be disposed between the 1-1 side S11 and the 1-2 side S12 in a plan view, and another portion of the driving voltage line PL may be disposed between the 2-1 side S21 and the 2-2 side S22 in a plan view.

Like the driving voltage line PL, first wiring W1 and second wiring W2 may be disposed on the fifth inorganic insulating layer 115. The organic insulating layer 116 may be disposed on the driving voltage line PL, the first wiring W1, and the second wiring W2. The first wiring W1 and the second wiring W2 may each extend in the second direction (for example, the y-axis direction). In detail, the first wiring W1 may be located adjacent to one side of the driving voltage line PL, and the second wiring W2 may be located adjacent to the other side of the driving voltage line PL. In other words, the second wiring W2 may be located opposite to the first wiring W1 with the driving voltage line PL disposed therebetween. In other words, the driving voltage line PL, the first wiring W1, and the second wiring W2 may be arranged to be spaced apart from each other in the first direction (for example, the x-axis direction). The first wiring W1, the driving voltage line PL, and the second wiring W2 are located sequentially in the first direction (in a +x direction).

The first wiring W1 may be the data line DL, and the second wiring W2 may be the initializing voltage line VL. In other words, the first wiring W1 may transmit the data signal Dm to the pixel circuit PC that is electrically connected to the first organic light-emitting diode OLED1, and the second wiring W2 may transmit the initializing voltage VINT to the pixel circuit PC that is electrically connected to the first organic light-emitting diode OLED1. The driving voltage line PL may transmit the first power supply voltage ELVDD to the pixel circuit PC that is electrically connected to the first organic light-emitting diode OLED1. However, the disclosure is not limited thereto. As described above, at least one of the plurality of signal lines SLn, SLn-1, EL, and DL, and/or at least one of the initializing voltage line VL and the driving voltage line PL may be shared by neighboring pixel circuits PC. Accordingly, the first wiring W1 may transmit the data signal Dm to the pixel circuit PC that is electrically connected to the second organic light-emitting diode OLED2, and the second wiring W2 may transmit the initializing voltage VINT to the pixel circuit PC that is electrically connected to the second organic light-emitting diode OLED2. The driving voltage line PL may transmit the first power supply voltage ELVDD to the pixel circuit PC that is electrically connected to the second organic light-emitting diode OLED2.

A portion of the first wiring W1 may be disposed below the 1-1 side S11 of the 1-1 electrode portion 211a and may extend along the 1-1 side S11. That is, the 1-1 side S11 may be disposed over the first wiring W1 to overlap the 1-1 side S11 in a plan view. A portion of the second wiring W2 may be disposed below the 1-2 side S12 of the 1-1 electrode portion 211a and may extend along the 1-2 side S12. That is, the 1-2 side S12 may be disposed over the second wiring W2 to overlap the −2 side S12 in a plan view. Accordingly, as shown in FIG. 5, a portion of the first wiring W1 may be disposed within the first opening OP1 in a plan view, and a portion of the second wiring W2 may also be disposed within the first opening OP1 in a plan view. In other words, a portion of the first wiring W1 may overlap the first opening OP1 in a plan view, and a portion of the second wiring W2 may also overlap the first opening OP1 in a plan view.

As described above, the first wiring W1 and the second wiring W2 may each extend in the second direction (for example, the y-axis direction). Accordingly, the portion of the first wiring W1 may be disposed below the 2-1 side S21 of the 2-1 electrode portion 212a and may extend along the 2-1 side S21. That is, the 2-1 side S21 may be disposed over the first wiring W1. A portion of the second wiring W2 may be disposed below the 2-2 side S22 of the 2-1 electrode portion 212a and may extend along the 2-2 side S22. That is, the 2-2 side S22 may be disposed over the second wiring W2. Accordingly, as shown in FIG. 5, a portion of the first wiring W1 may be disposed within the second opening OP2 in a plan view, and a portion of the second wiring W2 may also be disposed within the second opening OP2 in a plan view. In other words, the portion of the first wiring W1 may overlap the second opening OP2 in a plan view, and the portion of the second wiring W2 may also overlap the second opening OP2 in a plan view.

As described above, the driving voltage line PL, the first wiring W1, and the second wiring W2 may be arranged to be spaced apart from each other in the first direction (for example, the x-axis direction). Accordingly, a portion of the 1-1 electrode portion 211a may be disposed between the first wiring W1 and the driving voltage line PL in a plan view, and another portion of the 1-1 electrode portion 211a may be disposed between the driving voltage line PL and the second wiring W2 in a plan view. Similarly, a portion of the 2-1 electrode portion 212a may be disposed between the first wiring W1 and the driving voltage line PL in a plan view, and another portion of the 2-1 electrode portion 212a may be disposed between the driving voltage line PL and the second wiring W2 in a plan view.

The first wiring W1 and the second wiring W2 may be formed simultaneously with the driving voltage line PL and may be formed of the same material as the driving voltage line PL. Accordingly, the first wiring W1 and the second wiring W2 may be formed of the same material as the driving voltage line PL. In other words, each of the first wiring W1 and the second wiring W2 may include a conductive material. For example, each of the first wiring W1 and the second wiring W2 may include a metal material such as molybdenum (Mo), aluminum (Al), copper (Cu), or titanium (Ti), and may have a single-layer or multi-layer structure including the aforementioned materials. For example, the first wiring W1 and the second wiring W2 may each have a multi-layer structure of Ti/Al/Ti.

As described above, the organic insulating layer 116 may be interposed between the first wiring W1, the driving voltage line PL, and the second wiring W2 and the first pixel electrode 211. The organic insulating layer 116 may include an organic material. In general, an organic insulating layer contains an organic material. Thus, unlike an inorganic insulating layer containing an inorganic material, an upper surface of the organic insulating layer is substantially flat even when layers disposed below the organic insulating layer has an uneven surface. However, the upper surface of the organic insulating layer is not perfectly flat and has portions that have slightly uneven surface in areas corresponding to the components disposed below the organic insulating layer. That is, as shown in FIG. 6, the organic insulating layer 116 may have protrusions corresponding to the first wiring W1, the driving voltage line PL, and the second wiring W2.

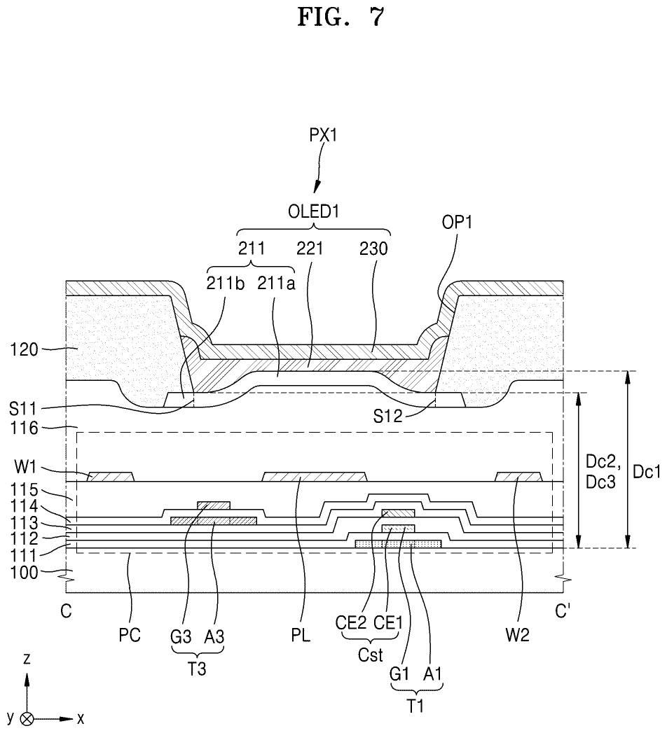

FIG. 7 is a schematic cross-sectional view of a display apparatus according to a comparative example. In detail, FIG. 7 is a view for explaining the uneven portions of an organic insulating layer and a pixel electrode on the organic insulating layer. As shown in FIG. 7, in the case of the display apparatus according to a comparative example, a 1-1 side S11 is not disposed over first wiring W1, and a 1-2 side S12 is not disposed over the second wiring W2. Accordingly, as shown in FIG. 7, the first wiring W1 is not disposed within first opening OP1 in a plan view, and a portion of the second wiring W2 is not disposed within the first opening OP1 either in a plan view. An organic insulating layer 116 may have the uneven portions in areas corresponding to the driving voltage line PL. Accordingly, an upper surface of the organic insulating layer 116 may have a slightly convex shape (in the +z direction) at a portion corresponding to the driving voltage line PL. Accordingly, the organic insulating layer 116 may have a gently-sloping upper surface near one side and the other side of the driving voltage line PL.

When a first pixel electrode 211 is disposed on the organic insulating layer 116 having this shape of an upper surface, the 1-1 electrode portion 211a may have a slightly convex shape with respect to the substrate 100. In detail, a portion of the 1-1 electrode portion 211a adjacent to the 1-1 side S11 may be tilted relative to the substrate 100 as shown in FIG. 7. That is, the portion of the 1-1 electrode portion 211a disposed adjacent to the 1-1 side S11 may be closer to the substrate 100 than a portion of the first pixel electrode 211 overlapping the driving voltage line PL. A portion of the 1-1 electrode portion 211a disposed adjacent to the 1-2 side S12 may also be tilted relative to the substrate 100 as shown in FIG. 7. That is, the portion of the 1-1 electrode portion 211a adjacent to the 1-2 side S12 may be closer to the substrate 100 than the portion of the first pixel electrode 211 overlapping the driving voltage line PL. In detail, a distance from an upper surface of the portion of the 1-1 electrode portion 211a overlapping the driving voltage line PL to the upper surface of the substrate 100 may be a first comparison distance Dc1. A distance from an upper surface of the portion of the 1-1 electrode portion 211a adjacent to the 1-1 side S11 to the upper surface of the substrate 100 may be a second comparison distance Dc2. The second comparison distance Dc2 may be less than the first comparison distance Dc1. A third comparison distance Dc3 from an upper surface of the portion of the 1-1 electrode portion 211a adjacent to the 1-2 side S12 to the upper surface of the substrate 100 may be less than the first comparison distance Dc1.

However, as shown in FIG. 6, in the case of the display apparatus 1 according to the present embodiment, the 1-1 side S11 of the 1-1 electrode portion 211a may be disposed over first wiring W1, and the 1-2 side S12 of the 1-1 electrode portion 211a may be disposed over the second wiring W2. The organic insulating layer 116 may have uneven portions in areas corresponding to the first wiring W1, the driving voltage line PL, and the second wiring W2. Accordingly, the upper surface of the organic insulating layer 116 may have a slightly convex shape (in the +z direction) at a portion corresponding to each of the first wiring W1, the driving voltage line PL, and the second wiring W2. Accordingly, the 1-1 electrode portion 211a of the display apparatus 1 according to the present embodiment may have a surface flatness greater than that of the 1-1 electrode portion 211a of the display apparatus according to a comparative example. In detail, a distance from the upper surface of the portion of the 1-1 electrode portion 211a overlapping the driving voltage line PL to the upper surface of the substrate 100 may be a first embodiment distance De1. A distance from the upper surface of the portion of the 1-1 electrode portion 211a overlapping the first wiring W1 to the upper surface of the substrate 100 may be a second embodiment distance De2. The second embodiment distance De2 may be the same as or similar to the first embodiment distance De1. A third embodiment distance De3 from the upper surface of the portion of the 1-1 electrode portion 211a overlapping the second wiring W2 to the upper surface of the substrate 100 may be the same as or similar to the first embodiment distance De1.

A distance from an upper surface of a portion of the 1-1 electrode portion 211a disposed between the first wiring W1 and the driving voltage line PL to the upper surface of the substrate 100 in a plan view may be a fourth embodiment distance De4. A distance from an upper surface of a portion of the 1-1 electrode portion 211a disposed between the second wiring W2 and the driving voltage line PL to the upper surface of the substrate 100 in a plan view may be a fifth embodiment distance De5. Each of the fourth embodiment distance De4 and the fifth embodiment distance De5 may be different from the first embodiment distance De1. In detail, each of the fourth embodiment distance De4 and the fifth embodiment distance De5 may be less than the first embodiment distance De1. However, a difference between the fourth embodiment distance De4 and the first embodiment distance De1 may not be large due to the first wiring W1, and a difference between the fifth embodiment distance De5 and the first embodiment distance De1 may not be large due to the second wiring W2. Because a distance between the driving voltage line PL and the first wiring W1, and a distance between the driving voltage line PL and the second wiring W2 in the present embodiment is less than a distance between the driving voltage line PL and the first wiring W1, and a distance between the driving voltage line PL and the second wiring W2 in the comparative example, a depth of a recess formed between the driving voltage line PL and the first wiring W1, and between the driving voltage line PL and the second wiring W2 in the present embodiment is less than a depth of a recess formed between the driving voltage line PL and the first wiring W1, and between the driving voltage line PL and the second wiring W2 in the comparative example. Accordingly, the 1-1 electrode portion 211a disposed on the inorganic insulating layer 116 in the present embodiment may have a substantially flat shape.

The description given above with reference to FIG. 6 regarding the distance from the upper surface of the 1-1 electrode portion 211a to the upper surface of the substrate 100 is equally applicable to a distance from the upper surface of the 2-1 electrode portion 212a to the upper surface of the substrate 100. Thus, repeated descriptions thereof will be omitted. In detail, a distance from an upper surface of a portion of the 2-1 electrode portion 212a overlapping the driving voltage line PL to the upper surface of the substrate 100 may be a sixth embodiment distance. A distance from an upper surface of a portion of the 2-1 electrode portion 212a overlapping the first wiring W1 to the upper surface of the substrate 100 may be a seventh embodiment distance. The seventh embodiment distance may be the same as or similar to the sixth embodiment distance. An eighth embodiment distance from an upper surface of the portion of the 2-1 electrode portion 212a overlapping the second wiring W2 to the upper surface of the substrate 100 may be the same as or similar to the sixth embodiment distance.

A distance from an upper surface of a portion of the 2-1 electrode portion 212a disposed between the first wiring W1 and the driving voltage line PL to the upper surface of the substrate 100 in a plan view may be a ninth embodiment distance. A distance from an upper surface of a portion of the 2-1 electrode portion 212a disposed between the second wiring W2 and the driving voltage line PL to the upper surface of the substrate 100 in a plan view may be a tenth embodiment distance. Each of the ninth and tenth embodiment distances may be different from the sixth embodiment distance. In detail, each of the ninth and tenth embodiment distances may be less than the sixth embodiment distance. However, a difference between the ninth embodiment distance and the sixth embodiment distance may not be large due to a reduced distance between the first wiring W1 and the driving voltage line PL, and a difference between the tenth embodiment distance and the sixth embodiment distance may not be large due to a reduced distance between the second wiring W2 and the driving voltage line PL. Accordingly, the 2-1 electrode portion 212a may have a substantially flat shape.

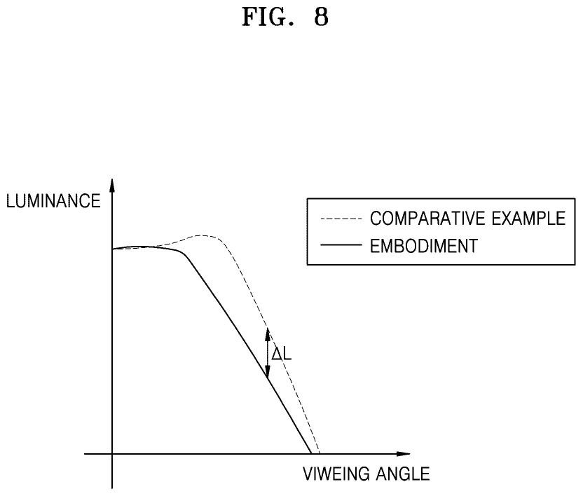

FIG. 8 is a graph schematically showing a change in luminance according to a change in viewing angle in a display apparatus. In the graph of FIG. 8, the horizontal axis represents a viewing angle and the vertical axis represents luminance. The viewing angle defines an angle in a direction (z-axis direction) perpendicular to the substrate 100 as 0 degrees, and refers to an angle between the direction (z-axis direction) perpendicular to the substrate 100 and a viewing direction. In the graph of FIG. 8, the solid line indicates a case where an upper surface of a pixel electrode portion disposed in an area corresponding to an opening is entirely approximately flat as shown in FIG. 6, and the dotted line indicates a case where a portion of the upper surface of the pixel electrode portion disposed in an area corresponding to the opening has a tilted portion as shown in FIG. 7. That is, the solid line in the graph of FIG. 8 indicates the case of the display apparatus 1 according to the present embodiment (hereinafter, referred to as an ‘embodiment’), and the dotted line in the graph of FIG. 8 indicates the case of a display apparatus according to a comparative example (hereinafter, referred to as a ‘comparative example’).

As can be seen in FIG. 8, compared to a comparative example, the luminance in an embodiment decreases relatively gently with an increase in the viewing angle. Because a pixel electrode according to a comparative example includes an tilted portion, light generated and emitted by an emission layer portion on the inclined surface is emitted with its optical axis shifted by the inclination of the inclined surface. Therefore, a side luminance ratio according to a comparative example increases compared to that according to an embodiment. However, because light generated and emitted by an emission layer according to an embodiment is not emitted with its optical axis tilted, the luminance according to an embodiment is relatively gently lowered with an increase in the viewing angle, compared to a comparative example.

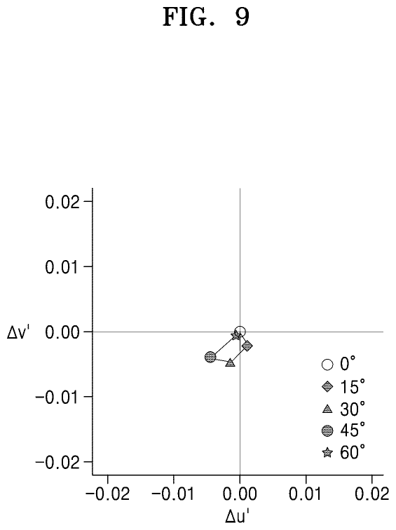

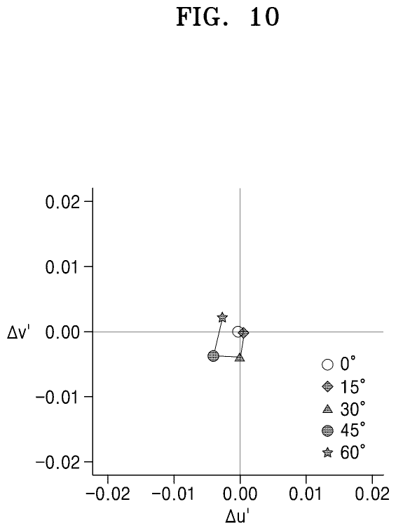

FIG. 9 is a graph schematically showing a change in color coordinates according to a change in viewing angle in the display apparatus 1 according to an embodiment. FIG. 10 is a graph schematically showing a change in color coordinates according to a change in viewing angle in the display apparatus according to a comparative example. That is, FIG. 9 is a graph in CIE 1976 color coordinates when an upper surface of a pixel electrode portion in an area corresponding to an opening is substantially flat as shown in FIG. 6. That is, FIG. 10 is a graph in CIE 1976 color coordinates when an upper surface of the pixel electrode portion in an area corresponding to the opening has a tilted portion as shown in FIG. 7. The color coordinates may vary depending on the physical properties and thicknesses of the components disposed over an emission layer, such as an opposite electrode, an encapsulation layer, or a capping layer, but the embodiment of FIG. 9 and the comparative example of FIG. 10 are the same as each other in terms of the physical properties and thicknesses of the components disposed over the emission layer.

In FIGS. 9 and 10, the horizontal axis indicates Δu′, the vertical axis indicates Δv′, and the coordinates of the center of the graph of FIG. 9 and the coordinates of the center of the graph of FIG. 10 are (0.00, 0.00). In such a graph as FIG. 9, when the color coordinates move toward a first quadrant, it means that a user perceives relatively more yellow, when the color coordinates move toward a second quadrant, it means that the user perceives relatively more green, when the color coordinates move toward a third quadrant, it means that the user perceives relatively more blue, and when the color coordinate moves toward a fourth quadrant, it means that the user perceives relatively more red. In FIGS. 9 and 10, a circle with uncolored interiors represents color coordinates at a viewing angle of 0°, a diamond with colored interiors represents color coordinates at a viewing angle of 15°, a triangle with colored interiors represents color coordinates at a viewing angle of 30°, a circle with colored interiors represents color coordinates at a viewing angle of 45°, and an asterisk with colored interiors represents color coordinates at a viewing angle of 60°.

As can be seen from FIGS. 9 and 10, compared to a comparative example, an embodiment has color coordinates adjacent to (0.00, 0.00). In particular, an embodiment has color coordinates adjacent to (0.00, 0.00) even at viewing angles of 450 and 60°. That is, compared to a comparative example, the change in color coordinates according to the change in viewing angle in an embodiment is small. Therefore, even when the viewing angle changes, a degree to which a viewer perceives a specific color more may decrease. Accordingly, the viewer may see a high-quality image.

According to an embodiment as described above, a display apparatus enabling a viewer to see a high-quality image may be realized. Of course, the scope of the disclosure is not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
an inorganic insulating layer disposed over a substrate;
a driving voltage line disposed on the inorganic insulating layer;
a first wiring disposed on the inorganic insulating layer and located adjacent to one side of the driving voltage line;
a second wiring disposed on the inorganic insulating layer and located adjacent to another side of the driving voltage line;
an organic insulating layer disposed on the driving voltage line, the first wiring, and the second wiring;
a pixel electrode disposed on the organic insulating layer; and
a pixel defining layer including an opening that exposes the pixel electrode,
wherein one edge of the pixel defining layer overlaps the first wiring in a plan view.

2. The display apparatus of claim 1, wherein another edge of the pixel defining layer which opposes the one edge of the pixel defining layer overlaps the second wiring in a plan view.

3. The display apparatus of claim 1, wherein the first wiring extends along the one edge of the pixel defining layer and the second wiring extends along another edge of the pixel defining layer which opposes the one edge of the pixel defining layer.

4. The display apparatus of claim 1, wherein a portion of the first wiring is disposed within the opening in a plan view and a portion of the second wiring is disposed within the opening in a plan view.

5. The display apparatus of claim 1, wherein a distance from an upper surface of a portion of the first electrode portion overlapping the driving voltage line to an upper surface of the substrate is equal to a distance from an upper surface of another portion of the first electrode portion overlapping the first wiring to the upper surface of the substrate.

6. The display apparatus of claim 5, wherein the distance from the upper surface of the portion of the first electrode portion overlapping the driving voltage line to the upper surface of the substrate is different from a distance from an upper surface of another portion of the first electrode portion disposed between the first wiring and the driving voltage line in a plan view to the upper surface of the substrate.

7. The display apparatus of claim 1, wherein a distance from an upper surface of a portion of the first electrode portion overlapping the driving voltage line to an upper surface of the substrate is equal to a distance from an upper surface of another portion of the first electrode portion overlapping the second wiring to the upper surface of the substrate.

8. The display apparatus of claim 7, wherein the distance from the upper surface of the portion of the first electrode portion overlapping the driving voltage line to the upper surface of the substrate is different from a distance from an upper surface of another portion of the first electrode portion disposed between the second wiring and the driving voltage line in a plan view to the upper surface of the substrate.

9. The display apparatus of claim 1, wherein the first wiring and the second wiring include a same material as the driving voltage line.

10. The display apparatus of claim 1, further comprising:
an emission layer disposed on the pixel electrode; and
an opposite electrode disposed on the emission layer.

11. A display apparatus comprising:
an inorganic insulating layer disposed over a substrate;
a driving voltage line disposed on the inorganic insulating layer;
a first wiring disposed on the inorganic insulating layer and located adjacent to one side of the driving voltage line;
a second wiring disposed on the inorganic insulating layer and located adjacent to another side of the driving voltage line;
an organic insulating layer disposed on the driving voltage line, the first wiring, and the second wiring;
a first pixel electrode disposed on the organic insulating layer;
a second pixel electrode disposed on the organic insulating layer; and
a pixel defining layer including a first opening and a second opening that expose the first pixel electrode and the second pixel electrode, respectively,
wherein the driving voltage line is disposed between the first wiring and the second wiring,
wherein one edge of the pixel defining layer overlaps the first wiring in a plan view, and
wherein another edge of the pixel defining layer which opposes the one edge of the pixel defining layer overlaps the second wiring in a plan view.

12. The display apparatus of claim 11, wherein the first wiring, the driving voltage line, and the second wiring are arranged to be spaced apart from each other in a first direction, the first pixel electrode and the second pixel electrode are arranged to be spaced apart from each other in a second direction that intersects the first direction, and the driving voltage line extends in the second direction.

13. The display apparatus of claim 12, wherein
the first wiring extends in the second direction, and
the second wiring extends in the second direction.

14. The display apparatus of claim 11, wherein a portion of the first wiring is disposed within the first opening in a plan view, another portion of the first wiring is disposed within the second opening in a plan view, a portion of the second wiring is disposed within the first opening in a plan view, and another portion of the second wiring is disposed within the second opening in a plan view.

15. The display apparatus of claim 11, wherein a distance from an upper surface of the first pixel electrode overlapping the driving voltage line to an upper surface of the substrate is equal to a distance from an upper surface of the first pixel electrode overlapping the first wiring to the upper surface of the substrate, and
wherein the distance from the upper surface of the first pixel electrode overlapping the driving voltage line to the upper surface of the substrate is different from a distance from an upper surface of the first pixel electrode disposed between the first wiring and the driving voltage line in a plan view to the upper surface of the substrate.

16. The display apparatus of claim 11, wherein a distance from an upper surface of the second pixel electrode overlapping the driving voltage line to an upper surface of the substrate is equal to a distance from an upper surface of the second pixel electrode overlapping the first wiring to the upper surface of the substrate, and
wherein the distance from the upper surface of the second pixel electrode overlapping the driving voltage line to the upper surface of the substrate is different from a distance from an upper surface of the second pixel electrode disposed between the first wiring and the driving voltage line in a plan view to the upper surface of the substrate.

17. The display apparatus of claim 11, wherein a distance from an upper surface of the first pixel electrode overlapping the driving voltage line to an upper surface of the substrate is equal to a distance from an upper surface of the first pixel electrode overlapping the second wiring to the upper surface of the substrate, and
wherein the distance from the upper surface of the first pixel electrode overlapping the driving voltage line to the upper surface of the substrate is different from a distance from an upper surface of the first pixel electrode disposed between the second wiring and the driving voltage line in a plan view to the upper surface of the substrate.

18. The display apparatus of claim 11, wherein a distance from an upper surface of the second pixel electrode overlapping the driving voltage line to an upper surface of the substrate is equal to a distance from an upper surface of the second pixel electrode overlapping the second wiring to the upper surface of the substrate, and
wherein the distance from the upper surface of the second pixel electrode overlapping the driving voltage line to the upper surface of the substrate is different from a distance from an upper surface of the second pixel electrode disposed between the second wiring and the driving voltage line in a plan view to the upper surface of the substrate.

19. The display apparatus of claim 11, wherein the first wiring and the second wiring include a same material as the driving voltage line.

20. The display apparatus of claim 11, further comprising:
a first emission layer disposed on the first pixel electrode;
a second emission layer disposed on the second pixel electrode; and
an opposite electrode disposed on the first emission layer and the second emission layer.
